(19) United States
(12) Patent Application Publication
(10) Pub. No.: US 2014/0083497 A1
(43) Pub. Date: Mar. 27, 2014

(54) Electrical Circuit and Method for Producing an Electrical Circuit

(71) Applicant: Robert Bosch GmbH, Stuttgart (DE)

(72) Inventors: Ricardo Ehrenpfordt, Korntal-Muenchingen (DE); Mathias Bruendel, Stuttgart (DE); Sonja Knies, Rutesheim (DE)

(73) Assignee: Robert Bosch GmbH, Stuttgart (DE)

(21) Appl. No.: 14/033,583

(22) Filed: Sep. 23, 2013

(30) Foreign Application Priority Data
Sep. 24, 2012 (DE) 10 2012 217 105.3

(51) Int. Cl. H01L 31/02

(52) U.S. Cl. CPC H01L 31/02021
USPC 136/256; 438/19

(57) ABSTRACT

An electrical circuit includes a solar cell having a photovoltaically active front side and a back side, and a redistribution wiring plane located on the back side of the solar cell. The redistribution wiring plane is electrically and mechanically connected to the solar cell. The electrical circuit also includes an electronic or micromechanical component located on a back-side side of the redistribution wiring plane facing away from the solar cell. The electronic or micromechanical component is electrically and mechanically connected to the redistribution wiring plane via a connection produced by a mounting and connection technology.

This application claims priority under 35 U.S.C. §119 to patent application no. DE 10 2012 217 105.3, filed on Sep. 24, 2012 in Germany, the disclosure of which is incorporated herein by reference in its entirety.

### BACKGROUND

The present disclosure relates to an electrical circuit and to a method for producing an electrical circuit.

The integration of energy converters is a trend in the field of electronic packaging arrangements. Solar cells especially are used alongside thermoelectric converters for obtaining electrical energy, e.g. for operating sensor modules.

US 2011/0169554 A1 describes an integrated solar-operated component.

### SUMMARY

Against this background, the present disclosure presents an electrical circuit and a method for producing an electrical circuit according to the main claims. Advantageous configurations are evident from the respective dependent claims and the following description.

By equipping a back side of the solar cell with a redistribution wiring plane, it is possible to arrange an electronic or a micromechanical component on the back side of the solar cell using known methods in the art of mounting and connection technology. It is thereby possible to realize a very compact circuit having its own energy supply via the solar cell.

A corresponding electrical circuit comprises the following features:

a solar cell having a photovoltaically active front side and a back side;
a redistribution wiring plane, which is arranged on the back side of the solar cell and is electrically and mechanically connected to the solar cell; and
an electronic or micromechanical component, which is arranged on a back-side side of the redistribution wiring plane facing away from the solar cell and is electrically and mechanically connected to the redistribution wiring plane via a connection produced by means of the mounting and connection technology.

The electrical circuit can be a sensor or an arbitrary electronic component. Accordingly, the component can be, for example, an integrated circuit, a sensor element or a measurement pickup. An integrated circuit can be, for example, an evaluation circuit for processing a sensor signal, a control circuit for controlling a function of the circuit, or a communication device for data transmission. A sensor element can be, for example, a temperature sensor, a force pickup or an acceleration sensor. The component can be a discrete, fully functional element which is applied to the redistribution wiring plane as a finished component. The solar cell can be a photovoltaic cell designed to convert radiation energy, for example sunlight, into electrical energy. The solar cell can be embodied in the form of a planar, thin wafer. The redistribution wiring plane can be embodied as a layer situated between the solar cell and the component. By way of example, the redistribution wiring plane can be applied on a back side of a substrate of the solar cell. A thickness of the redistribution wiring plane can be thinner than a thickness of the component or a thickness of the solar cell. The redistribution wiring plane can be designed to produce a mechanical connection between the component and the solar cell. Furthermore, the redistribution wiring plane can be designed to provide an energy provided by the solar cell to the component directly or via an interposed energy store. For this purpose, the redistribution wiring plane can have suitable electrical conductor tracks and contact areas. It is also possible for a plurality of electronic or micromechanical components to be arranged on the back side of the redistribution wiring plane. The component can be a discrete element which can be produced independently of the solar cell and can be connected as a finished element to the redistribution wiring plane via the connection.

Mounting and connection technology, as an area of microelectronics and microsystems engineering, encompasses the totality of the technologies and design tools which are required for mounting microelectronic components.

Using mounting and connection technology, the component can be connected to the redistribution wiring plane by means of known methods. The art of mounting and connection technology can encompass a cohesive joining method. Consequently, the component can be connected to the redistribution wiring plane via a cohesive joining connection. By way of example, the connection can run between an electrical contact area of the component and an electrical contact area of the redistribution wiring plane.

In contrast to a redistribution wiring layer that is produced separately and subsequently placed onto the solar cell, for example in the form of an adhesively bonded printed circuit board or an adhesively bonded circuit carrier, the redistribution wiring layer in accordance with one embodiment may have been produced by a production method in which the redistribution wiring layer is produced directly on the back side of the solar cell. The solar cell can thus be used as a substrate for mounting the redistribution wiring layer. In this case, the redistribution wiring plane can be built up layer by layer by forming individual layers on the back side of the solar cell. The redistribution wiring plane can thus be produced without a separately produced layer composite being applied to the back side of the solar cell. Traditional semiconductor production methods can be used for producing the redistribution wiring plane on the back side of the solar cell. The redistribution wiring plane can be produced in an extended process for the production of the solar cell.

By way of example, the redistribution wiring plane can be realized by a layer construction composed of a plurality of layers applied to the back side of the solar cell in sequential succession. The layers applied temporally successively to the back side of the solar cell can comprise, for example, one or a plurality of electrical insulation layers, one or a plurality of passivation layers and at least one electrically conductive layer. Consequently, at least one of the plurality of layers applied to the back side of the solar cell in sequential succession can be an electrically conductive layer. Moreover, the redistribution wiring plane can have at least two electrically conductive layers applied to the back side of the solar cell layer by layer in sequential succession. A conductive layer can be embodied as a metallization layer.

By way of example, the connection can be produced by means of soldering, adhesive bonding or wire bonding, or a combination of these methods. Corresponding materials that form the connection may have been arranged on the component or on the redistribution wiring plane beforehand. The connection can be produced by known methods rapidly, cost-effectively and in a space-saving manner.

The electronic or micromechanical component can be embodied as an application-specific integrated circuit, as an integrated circuit or as a microsystem. Even complex functions can be realized by means of an application-specific integrated circuit, also called ASIC. The microsystem can be a so-called MEMS (microelectromechanical system). A respectively suitable component can be selected depending on the field of application. Moreover, components of different types can be combined and can be arranged alongside one another or else in a manner stacked one above another on the redistribution wiring plane.

In accordance with one embodiment, the electrical circuit can comprise a store for electrical energy. By way of example, the store can be arranged on the back-side side of the redistribution wiring plane. In this case, the store can be electrically and mechanically connected to the redistribution wiring plane by means of a connection produced by the art of mounting and connection technology. Furthermore, the store can be connected between an electrical terminal contact of the solar cell and an electrical terminal contact of the electronic or micromechanical component. The store can be, for example, a galvanic element, for example a rechargeable battery or a capacitor. As an alternative to an arrangement of the store on the back-side side of the redistribution wiring plane, the store can also be arranged at some other suitable position of the switch. By means of the store, electrical energy can be provided to the component even when the solar cell provides no energy or does not provide enough energy for the operation of the component.

By way of example, the redistribution wiring plane can be embodied as a back-side metallization of the solar cell. By way of example, the back-side metallization may have been applied to a surface of a substrate of the solar cell. Known metallization methods can be used for this purpose.

The redistribution wiring plane can have at least one structured metal layer for the redistribution wiring of electrical signals of the component and for the electrical contact-connection of the solar cell and of the component. The metal layer can consist of aluminum or copper, for example. The structured metal layer may have been applied on the back side of the solar cell by a whole-area deposition and subsequent structuring, by electrodeposition or by chemical mechanical planarization, for example. By virtue of the fact that the metal layer has a structuring, it is possible to realize conductor tracks, for example, by which individual contact areas of the redistribution wiring plane can be electrically conductively connected to one another. Moreover, corresponding contact areas can be provided by the structured metal layer. The redistribution wiring plane can have a plurality of structured metal layers arranged in a stacked fashion. Conductor tracks running in a transposed fashion can be realized in this way.

The solar cell can have a plated-through hole in order to electrically conductively connect the front side of the solar cell to the redistribution wiring plane. In this way, an electrical contact-connection of the active front side of the solar cell can be realized in a space-saving and fail-safe manner.

The electrical circuit can comprise an encapsulation compound. The encapsulation compound can be arranged on the back-side side of the redistribution wiring plane and enclose the component. A housing for the component or for the electrical circuit can be formed by the encapsulation compound in a simple manner.

In accordance with one embodiment, the encapsulation compound can have at least one plated-through hole. By way of example, the active front side of the solar cell can be electrically contact-connected via such plated-through holes. In this case, one plated-through hole can be led to the redistribution wiring plane. A further plated-through hole can be led past the solar cell in order to be able to make electrical contact with the active front side of the solar cell.

The electrical circuit can comprise a substrate, wherein an edge region of the substrate bears against an edge region of the front side of the solar cell. In this case, an electrically conductive connection between the front side of the solar cell and the redistribution wiring plane can be led via the substrate. By way of example, the edge region of the substrate can enclose the front side of the solar cell over the full extent. A main region of the front side of the solar cell may be situated in the region of a through-opening in the substrate and may therefore not be covered by the substrate. The use of the substrate enables the electrical circuit to be embodied in a very stable fashion.

A method for producing an electrical circuit comprises the following steps:

providing a solar cell having a photovoltaically active front side and a back side;
applying, layer by layer, a plurality of layers to the back side of the solar cell, in order to form a redistribution wiring plane on the back side of the solar cell, and electrically and mechanically connecting the redistribution wiring plane to the solar cell; and
arranging an electronic or micromechanical component on a back-side side of the redistribution wiring plane facing away from the solar cell, and producing a connection by means of mounting and connection technology in order to electrically and mechanically connect the component to the redistribution wiring plane.

The step of applying the redistribution wiring plane layer by layer can be carried out by means of a metallization process, for example. In this case, at least two layers can be applied. The redistribution wiring plane can extend over a complete area of the back side of the solar cell or over a partial region of the back side.

In this way, it is possible to produce an electronic and sensor packaging system on the basis of a substrate with solar-energy converter functionality. In this case, it is possible to have recourse to mounting and connection technology in which the use of thin silicon substrates has become established. The latter afford advantages, inter alia, in terms of the thermomechanical behavior and can be provided with through-contacts and conductor tracks in a very fine pitch.

Furthermore, it is possible to use methods for the large-area encapsulation of semiconductor components which are available as a result of the improvement of molding technology. In “compression molding”, areas having a diameter of 300 mm can be coated with polymeric encapsulation materials without any problems. With the use of temporary carriers for the semiconductor components, an additional substrate can be dispensed with in this case.

In order to develop compact, autonomous sensors it is necessary to provide the energy necessary for operation by conversion from other forms of energy. This is made possible by the cost-effective and small-design integration of photovoltaic cells into autonomous sensor modules.

A corresponding circuit is based on a stacked substrate-component composite assembly, comprising at least one photovoltaic cell which converts radiation energy into electrical energy, furthermore comprising at least one electronic and/or micromechanical component which comprises contact areas for electrical and mechanical contact-making, furthermore comprising structured metal layers for the redistribution wiring of electrical signals, characterized in that the at least one electronic and/or micromechanical component is fixed on the back side opposite to the radiation-sensitive front side of the photovoltaic cell, such that this constitutes a component-substrate composite assembly having strong mechanical adhesion and the structured metallization applied on the back side opposite to the radiation-active front side of the photovoltaic cell has at least one electrical connection between the electronic and/or micromechanical component and the radiation-active front side of the photovoltaic cell.

A circuit in accordance with the approach described is distinguished by a high cost-effectiveness. The solar cell is mountable as substrate in multi-use and no further adhesive-bonding technique is required for the integration of the solar cell. A further advantage consists in low use of material, a small structural size of flat design and short electrical conduction paths as a result of the use of the solar cell as a substrate with direct conductor track routing as a metallization layer. Furthermore, a low thermomechanical mismatch occurs as a result of silicon as substrate material and component material and there is no loss of photovoltaic efficiency as a result of shading effects.

### BRIEF DESCRIPTION OF THE DRAWINGS

The disclosure is explained in greater detail by way of example below with reference to the accompanying drawings, in which:

FIGS. 1 to 4 show schematic illustrations of circuits in accordance with exemplary embodiments of the present disclosure; and

FIG. 5 shows a flowchart of a method for producing an electrical circuit in accordance with one exemplary embodiment of the present disclosure.

### DETAILED DESCRIPTION

In the following description of preferred exemplary embodiments of the present disclosure, identical or similar reference signs are used for the similarly acting elements illustrated in the different figures, a repeated description of these elements being dispensed with.

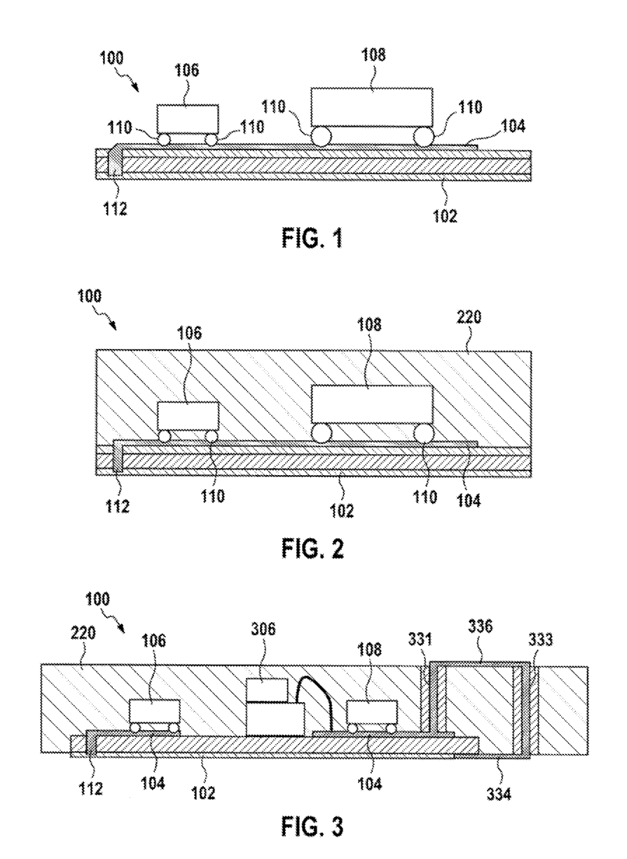

FIG. 1 shows a schematic illustration of a circuit 100 in accordance with one exemplary embodiment of the present disclosure. The circuit 100 comprises a solar cell 102, also called photovoltaic cell, a redistribution wiring plane 104, also called redistribution wiring, and in accordance with this exemplary embodiment two components 106, 108. The components 106, 108 are electrically and mechanically connected to the redistribution wiring plane 104 via connections 110.

The solar cell 102 can be constructed from semiconductor materials in a manner corresponding to known solar cells. The solar cell 102 can have a suitable layer construction. The solar cell 102 has a photovoltaically active front side, which is arranged at the bottom in the illustration shown in FIG. 1. The front side of the solar cell 102 has a planar surface, which can be rectangular, for example. The solar cell 102 is designed to convert radiation incident on the active front side into electrical energy and to provide said electrical energy at terminals of the solar cell 102. At least one front-side terminal of the solar cell 102 can be arranged on the front side of the solar cell and at least one back-side terminal of the solar cell 102 can be arranged on the back side of the solar cell 102. During the operation of the solar cell 102, an electrical voltage is present between the front-side terminal and the back-side terminal, which electrical voltage can be used for operating the components 106, 108.

The redistribution wiring plane 104 extends over a back side of the solar cell 102 arranged opposite the front side. In accordance with this exemplary embodiment, the redistribution wiring plane 104 extends over a central region of the back side. An edge region of the back side of the solar cell 102 is not covered by the redistribution wiring plane 104. The redistribution wiring plane 104 is mechanically fixedly connected to the back side of the solar cell 102. The redistribution wiring plane 104 is designed to provide an electrical energy required for the operation of the components 106, 108 from the terminals of the solar cell 102 to contacts of the components 106, 108. Furthermore, the redistribution wiring plane 104 is designed to conduct electrical signals depending on the embodiment of the circuit 100 and of the components 106, 108 between contacts of the components 106, 108 or between contacts of the components 106, 108 and external contacts of the circuit. For this purpose, the redistribution wiring plane 104 can have a plurality of conductor tracks. The redistribution wiring plane 104 can have one or a plurality of layers. If the redistribution wiring plane 104 has a plurality of layers, then conductor tracks can be realized in a transposed fashion. The redistribution wiring plane 104 can be embodied as a back-side metallization of the solar cell 102. For this purpose, by means of a suitable method, a structured or non-structured metal layer can be applied to the back side of the solar cell 102. If a non-structured metal layer is applied, then it can subsequently be structured in order to shape the redistribution wiring plane 104. In order to form a multilayered redistribution wiring plane 104, two or more metal layers can be applied successively.

In accordance with this exemplary embodiment, at least one plated-through hole 112 is led through the layer construction of the solar cell 102. The plated-through hole 112 produces an electrically conductive connection between the front-side terminal of the solar cell 102 and the redistribution wiring plane 104 arranged on the back side of the solar cell 102. In this way, an electrical voltage generated by the solar cell 102 can be provided to the redistribution wiring plane 104 from the front side of the solar cell 102. Via a direct contact-connection, the redistribution wiring plane 104 can be electrically conductively connected directly to a back-side terminal of the redistribution wiring plane 104.

The components 106, 108 can be embodied as electronic or micromechanical components. The components 106, 108 can be electronic components, for example. Exemplary embodiments of the components 106, 108 are integrated circuits or microsystems. The components 106, 108 can be embodied differently. By way of example, the component 106 can be embodied as an electronic component and the component 108 can be embodied as a micromechanical component.

The connections 110 can be produced by means of a known art of mounting and connection technology. By way of example, the connections 110 can be soldering connections, adhesive-bonding connections or bonding connections. In accordance with this exemplary embodiment, the components 106, 108 are equipped with bumps and fixed by means of the bumps on a surface of the redistribution wiring plane 104 that faces the components 106, 108. Various techniques in the art of mounting and connection technology can also be used for making contact with the components 106, 108 at the redistribution wiring plane.

In accordance with one exemplary embodiment, by way of example, the component 106 can be embodied as a store for electrical energy. Such a store is designed to buffer-store the energy generated by the solar cell 102 and to output it as required to the further component 108 in order to enable the component 108 to be operated independently of an activity of the solar cell 102.

A circuit 100 in accordance with one exemplary embodiment of the present disclosure is described below with reference to FIG. 1. In this case, the circuit 100 is embodied as a solar cell 102 equipped with and contact-connected to electronic components 106, 108 on the back side. The components 104, 106 can be bare dies, packaged sensors, e.g. molded packages, or sensor modules. The electrical contact-connection between the components 106, 108 and the redistribution wiring plane 104 embodied as back-side metallization can be effected by flip-chip technology, and the electrical connection to the front side of the photovoltaic cell 102 can be effected via electrical through-contacts 112. Further components 106, 108 can be applied alongside one another or else one above another and can be contact-connected to the photovoltaic cell 102 or from component 106 to component 108.

FIG. 2 shows a schematic illustration of a circuit 100 in accordance with one exemplary embodiment of the present disclosure. The circuit 100 is embodied in a manner corresponding to the circuit described with reference to FIG. 1, but additionally has an encapsulation compound 220. The encapsulation compound 220 is arranged on the back side of the circuit 100 and encapsulates the components 106, 108 and exposed regions of the redistribution wiring plane 104 and regions of the back side of the solar cell 102 that are not covered by the redistribution wiring plane 104. A thickness of the layer of the encapsulation compound 220 can be chosen such that the components 106, 108 are completely enclosed by the encapsulation compound 220. Depending on the embodiment, the encapsulation compound 220 can be embodied for example as a potting compound or a molding compound.

In accordance with one exemplary embodiment, the circuit 100 is a solar cell 102 which is equipped with electronic components 106, 108 on the back side, is mechanically and electrically contact-connected by flip-chip technology and is encapsulated with the encapsulation compound 220.

In accordance with one exemplary embodiment, the back side of the solar cell 102 is encapsulated with a polymer in a subsequent process in order to protect the back side and the components 106, 108. This can be done e.g. by lamination, encapsulation by injection molding, casting, transfer molding, or molding. It is possible to process cells 102 that have already been singulated, and it is equally possible to encapsulate a plurality of systems as a whole and subsequently singulate them. Furthermore, encapsulations by metal covers, for example for EMC shielding, premolded plastic covers or films laminated over are also conceivable.

FIG. 3 shows a schematic illustration of a circuit 100 in accordance with one exemplary embodiment of the present disclosure. The circuit 100 is constructed similarly to the circuit shown in FIG. 2.

The circuit 100 comprises a solar cell 102, on the back side of which components 106, 108, 306 are arranged. Two regions of the redistribution wiring plane 104 arranged in a manner spaced apart from one another are shown on the back side of the solar cell 102. The regions of the redistribution wiring planes 104 can be electrically insulated from one another or electrically connected to one another, depending on the exemplary embodiment.

As described with reference to FIG. 1, the component 106 is arranged on that region of the redistribution wiring plane 104 which is shown on the left in FIG. 3. This region of the redistribution wiring plane 104 is electrically conductively connected to the front side of the solar cell 102 via a plated-through hole 112. As described with reference to FIG. 1, the component 108 is arranged on that region of the redistribution wiring plane 104 which is shown on the right in FIG. 3.

The component 306 is arranged in a section of the back side of the solar cell 102 that lies between the regions of the redistribution wiring plane 104. The component 306 is mechanically fixed to the back side of the solar cell 102, for example by means of an adhesive-bonding connection. The component 306 is shown by way of example as an arrangement comprising two component elements stacked one above the other. The component 306 is connected via an electrical line, for example a bonding wire, to that region of the redistribution wiring plane 104 on which the component 108 is arranged. For this purpose, the electrical line is led from a surface of the redistribution wiring plane 104 to a top side of the lower component element of the component 306, that is to say the component element arranged on the back side of the solar cell 102.

An encapsulation compound 222 encapsulates, as described with reference to FIG. 2, the components 106, 108, 306 and the back side of the solar cell 102 or the regions of the redistribution wiring plane 104 that are arranged on the back side of the solar cell 102. Furthermore, the encapsulation compound 222 is led beyond lateral edges of the solar cell 102, such that the solar cell 102, apart from the active front side of the solar cell 102, is embedded in the encapsulation compound 222.

That region of the redistribution wiring plane 104 on which the component 108 is arranged is electrically conductively connected to the front side of the solar cell 102 via a first plated-through hole 331, a second plated-through hole 333, a lower conductor track 334 and an upper conductor track 336. The first plated-through hole 331 is led from the redistribution wiring plane 104 to an outer surface of the encapsulation compound 220 facing the redistribution wiring plane 104. The upper conductor track 336 extends on the outer surface of the encapsulation compound between the first plated-through hole 331 and the second plated-through hole 333. The second plated-through hole 333 extends through the complete thickness of the encapsulation compound 220 in a region extending beyond a lateral edge of the solar cell 102. The lower conductor track 334 extends over a surface of the encapsulation compound 220 that runs at the level of the front side of the solar cell 102 between the front side of the solar cell 102 and the second plated-through hole. The lower conductor track 334 is designed to electrically connect the active front side of the solar cell 102 to the second plated-through hole 333.

The encapsulation compound 220 can be embodied as a molding compound, for example. In this case, the plated-through holes 331, 333 can be embodied as molded through-contacts.

In accordance with one exemplary embodiment, the circuit 100 is embodied as a design with a substrateless housing. The solar cell 102 is electrically connected to back-side mounted components 106, 108, 306 in the form of chips via a redistribution wiring plane 104 and through-contacts 331, 333 in the encapsulation compound 220. The components 106, 108 are contact-connected by means of flip-chip technology both mechanically and electrically or by means of wire bonding technology electrically to adhesively bonded components 306. The redistribution wiring plane 104 is realized in the form of metalized redistribution wiring layers arranged between the back side of the photovoltaic cell 102 and the mold underside of the encapsulation compound 220.

In this case, the solar cell front side can be contact-connected technologically by through-contacts 112 in the cell 102 itself (“through silicon via”) or else in the encapsulation compound 220. In this case, the contact-connection in the encapsulation compound is conceivable in a traditional fashion as wire bonding technology, but also as a metallic through-contact 331, 333 in the encapsulation compound 220. This last is relevant especially when a substrateless process is used for producing the encapsulation 220, e.g. on the basis of eWLB technology (Embedded Wafer Level Ball Grid Array Technology). In this case, it is unimportant whether the through-contact 112, 331, 333 is realized directly in the encapsulation compound 220 or in an element 102 embedded therein. One specific embodiment is a “package-on-package” design, in which the top side of the encapsulation compound 220 can be used as a redistribution wiring plane for mounting further bare dies or packaged components (not illustrated).

FIG. 4 shows a schematic illustration of a circuit 100 in accordance with one exemplary embodiment of the present disclosure. The circuit 100 is constructed similarly to the circuit shown in FIG. 3, but redistribution wiring plane 104 is not connected to the active front side of the solar cell 102 via plated-through holes.

The circuit 100 comprises a substrate 334, which forms a part of an outer surface of the circuit 100. The substrate 334 is embodied as a structured substrate. The substrate 334 has a through-opening in an inner region. The solar cell 102 is placed with the active front side ahead onto the substrate 334 in such a way that the through-opening of the substrate 334 is closed by the active front side of the solar cell 102. Edge sections of the solar cell 102 thus bear on edges of the substrate 334 that face the through-opening. The substrate 334 extends laterally beyond an outer edge of the solar cell 102. On a back side of the substrate facing the solar cell 102, the substrate 334 has one or a plurality of conductor tracks. One such conductor track of the substrate 334 is electrically conductively connected to the active front side of the solar cell 102 and extends laterally beyond an edge of the solar cell 102. The conductor track is connected to the redistribution wiring plane 104 via one or a plurality of electrical lines 341, for example in the form of wire bonds.

FIG. 4 shows an electrical line 341, which connects that region of the redistribution wiring plane 104 which is provided for making contact with the component 106 to the active front side of the solar cell 102, and a further electrical line 341, which connects that region of the redistribution wiring plane 104 which is provided for making contact with the components 108, 306 to the active front side of the solar cell 102.

In a manner corresponding to the exemplary embodiment shown in FIG. 3, the circuit shown in FIG. 4 comprises an encapsulation compound 220. Besides the components 106, 108, 306, the redistribution wiring plane 104 and the back side of the solar cell 102, the encapsulation compound additionally covers the back side of the substrate 334 or the conductor tracks situated on the back side of the substrate 334 and encapsulates the electrical lines 341.

A front side of the substrate 334 is exposed, as is a region of the front side of the solar cell 102 that does not bear on the substrate 334.

In accordance with one exemplary embodiment, the circuit 100 shown in FIG. 4 is realized in a design in which the solar cell 102 is applied as flip-chip to the substrate 334. In this case, the contact-connection of the active side of the solar cell 102 can be realized e.g. by solder, conductive adhesive or similar flip-chip contact-connections.

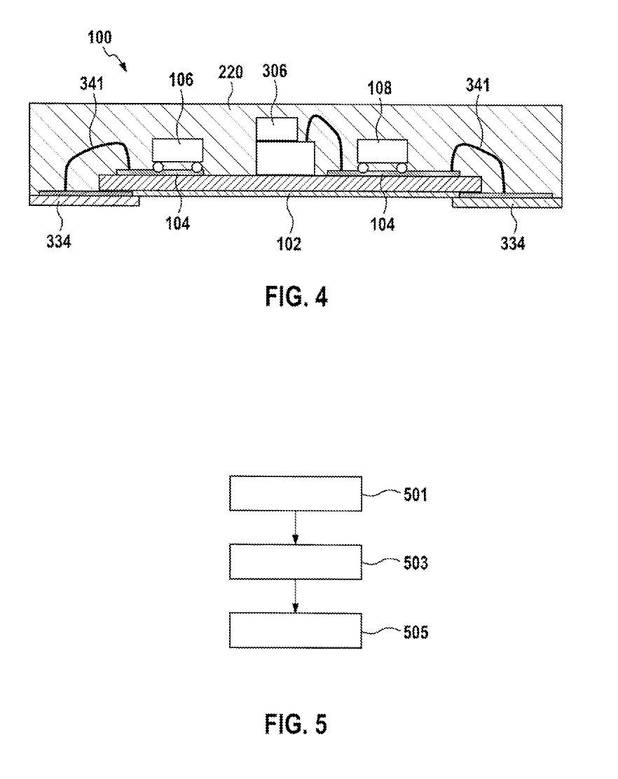

FIG. 5 shows a flowchart of a method for producing an electrical circuit in accordance with one exemplary embodiment of the present disclosure. The circuit can be a circuit as shown in the previous figures.

A step 501 involves providing a solar cell having a photovoltaically active front side and back side arranged opposite the front side.

A step 503 involves arranging a redistribution wiring plane on the back side of the solar cell. In this case, the redistribution wiring plane is mechanically connected to the back side of the solar cell. At the same time or in a separate subsequent step, the redistribution wiring plane is electrically connected to an electrical contact of the solar cell. The redistribution wiring plane is formed by temporally successive application of the individual layers by which the redistribution wiring plane is shaped.

A step 505 involves arranging at least one electronic or micromechanical component on a back-side side of the redistribution wiring plane facing away from the solar cell. At the same time or in a step performed subsequently, the at least one component is electrically and mechanically connected to the redistribution wiring plane. Mounting and connection technology is used in this case. By way of example, the at least one component can be provided as a discrete component and can be arranged on the redistribution wiring plane and can subsequently be fixed to the redistribution wiring plane by means of a soldering process or an adhesive-bonding process, for example.

In a further step, the at least one component can be encapsulated by an encapsulation compound. In this case, the electrical contact-connection between the solar cell and the redistribution wiring plane can be implemented only after the encapsulation compound has been applied. This may be the case for example when the electrical contact-connection is made via plated-through holes running through the encapsulation compound.

Technology for the integration of the solar cell 102 with the other elements 106, 108, 306, for example in the form of an ASIC, IC or MEMS, is described with reference to the previous figures. The technology is based on the production of a suitable redistribution wiring plane 104 on the back side of the solar cell 102 and the application of components 106, 108, 306 by techniques of mounting and connection technology such as, for example, soldering, adhesive bonding or wire bonding, wherein a mechanical and electrical connection between the solar cell 102 and the elements 106, 108 is produced through the redistribution wiring 104, even if the electrical connection is realized only indirectly e.g. via an interposed battery.

An application of the design described is possible for energy-autonomous sensors, for example. The exemplary embodiments described and shown in the figures have been chosen merely by way of example. Different exemplary embodiments can be combined with one another completely or with regard to individual features. Moreover, one exemplary embodiment can be supplemented by features of a further exemplary embodiment. Furthermore, method steps according to the disclosure can be performed repeatedly and in a different order than that described. If an exemplary embodiment comprises an “and/or” combination between a first feature and a second feature, then this should be interpreted such that the exemplary embodiment has both the first feature and the second feature in accordance with one embodiment and has either only the first feature or only the second feature in accordance with a further embodiment.

What is claimed is:

1. An electrical circuit comprising:
a solar cell including a photovoltaically active front side and a back side;
a redistribution wiring plane located on the back side of the solar cell, the redistribution wiring plane being electrically and mechanically connected to the solar cell; and
an electronic or micromechanical component located on a back-side side of the redistribution wiring plane facing away from the solar cell, the electronic or micromechanical component being electrically and mechanically connected to the redistribution wiring plane via a connection produced by a mounting and connection technology.

2. The electrical circuit according to claim 1, wherein the redistribution wiring plane is formed with a layer construction composed of a plurality of layers applied to the back side of the solar cell in sequential succession.

3. The electrical circuit according to claim 2, wherein at least one layer of the plurality of layers applied to the back side of the solar cell in sequential succession is an electrically conductive layer.

4. The electrical circuit according to claim 1, wherein the connection produced by the mounting and connection technology includes at least one of soldering, adhesive bonding, and wire bonding.

5. The electrical circuit according to claim 1, wherein the electronic or micromechanical component includes an application-specific integrated circuit, as an integrated circuit or as a microelectromechanical system.

6. The electrical circuit according to claim 1, further comprising:
a store for electrical energy located on the back-side side of the redistribution wiring plane, the store being electrically and mechanically connected to the redistribution wiring plane by the connection produced by the mounting and connection technology, and the store being electrically connected between at least one electrical terminal contact of the solar cell and at least one electrical terminal contact of the electronic or micromechanical component.

7. The electrical circuit according to claim 1, wherein the redistribution wiring plane includes at least one structured metal layer for the redistribution wiring of electrical signals of the component and for the electrical contact-connection of the solar cell and of the component.

8. The electrical circuit according to claim 1, wherein the solar cell includes a plated-through hole configured to electrically conductively connect the front side of the solar cell to the redistribution wiring plane.

9. The electrical circuit according to claim 1, further comprising:
an encapsulation compound located on the back-side side of the redistribution wiring plane, the encapsulation compound being configured to enclose the component.

10. The electrical circuit according to claim 1, further comprising:
a substrate defining an edge region configured to bear against an edge region of the front side of the solar cell,
wherein an electrically conductive connection between the front side of the solar cell and the redistribution wiring plane is led via the substrate.

11. A method for producing an electrical circuit comprising:
providing a solar cell including a photovoltaically active front side and a back side;
applying, layer by layer, a plurality of layers to the back side of the solar cell, in order (i) to form a redistribution wiring plane on the back side of the solar cell, and (ii) to electrically and mechanically connect the redistribution wiring plane to the solar cell; and
arranging an electronic or micromechanical component on a back-side side of the redistribution wiring plane facing away from the solar cell, a mounting and connection technology being configured to produce a connection configured to electrically and mechanically connect the component to the redistribution wiring plane.
